(19) United States
(12) Patent Application Publication
(10) Pub. No.: US 2016/0165760 A1
(43) Pub. Date: Jun. 9, 2016

(54) RACK AND METHOD OF COOLING ELECTRONIC DEVICE

(71) Applicant: FUJITSU LIMITED, Kawasaki-shi (JP)

(72) Inventor: Tomoko Kutsuzawa, Yokohama (JP)

(21) Appl. No.: 14/852,736

(22) Filed: Sep. 14, 2015

(30) Foreign Application Priority Data
Dec. 3, 2014 (JP) 2014-244983

(51) Int. Cl. H05K 7/20

(52) U.S. Cl. CPC H05K 7/20736; H05K 7/20836

(57) ABSTRACT

A cooling device includes: a rack body that houses a plurality of pieces of electronic equipment; a plurality of temperature sensors that detect temperatures of air discharged from a plurality of exhaust ports of the rack body; and an opening and closing device that increases an opening ratio of an exhaust port in which a temperature of the air detected with a temperature sensor is equivalent to or higher than a threshold temperature, and that decreases an opening ratio of an exhaust port in which a temperature of the air is lower than the threshold temperature.

### CROSS-REFERENCE TO RELATED APPLICATION

This application is based upon and claims the benefit of priority of the prior Japanese Patent Application No. 2014-244983, filed on Dec. 3, 2014, the entire contents of which are incorporated herein by reference.

### FIELD

The exemplary embodiments discussed herein are related to a rack and a method of cooling an electronic device.

### BACKGROUND

There is a rack for a plurality of pieces of electronic equipment in which movable louvers that individually control a flow rate of air sent into the electronic equipment from an intake fan are disposed at positions corresponding to each of the electronic equipment and in which a controller, based on intake air temperatures and exhaust air temperatures of the electronic equipment that have been measured by temperature sensors, controls the opening and closing of the relevant louvers.

Furthermore, there is an electronic device cooling device that controls the amount of air flowing into a plurality of package chambers by detecting each temperature in the package chambers and by opening and closing air exhaust ports with slide plates in accordance with the detected temperatures.

Furthermore, there is a printer in which temperatures of thermal heads of a plurality of print units are each measured and in which, when there is a thermal head exceeding a specified temperature, an exhaust fan is rotated and a shutter plate of a relevant housing portion is moved to an open position such that external air is drawn into the housing portion.

For example, Japanese Laid-open Patent Publication No. 2009-123887, Japanese Laid-open Patent Publication No. 10-135676, and Japanese Laid-open Patent Publication No. 2004-203013 are documents related to the techniques described above.

### SUMMARY

In accordance with an aspect of the embodiments, a cooling device includes: a rack body that houses a plurality of pieces of electronic equipment; a plurality of temperature sensors that detect temperatures of air discharged from a plurality of exhaust ports of the rack body; and an opening and closing device that increases an opening ratio of an exhaust port in which a temperature of the air detected with a temperature sensor is equivalent to or higher than a threshold temperature, and that decreases an opening ratio of an exhaust port in which a temperature of the air is lower than the threshold temperature.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

These and/or other aspects and advantages will become apparent and more readily appreciated from the following description of the embodiments, taken in conjunction with the accompanying drawing of which:

FIG. 1 is a side view illustrating an electronic device system of a first exemplary embodiment;

FIG. 2 is a perspective view illustrating an electronic device of the first exemplary embodiment;

FIG. 3 is a perspective view illustrating the electronic device of the first exemplary embodiment;

FIG. 4 is a side view illustrating the electronic device of the first exemplary embodiment in a partially enlarged manner;

FIG. 5 is a flowchart illustrating an example of a control performed in an electronic device cooling method;

FIG. 6 is a flowchart illustrating an example of a control performed in an electronic device cooling method;

FIG. 7 is a side view illustrating the electronic device system of the first exemplary embodiment;

FIG. 8 is a side view illustrating the electronic device system of the first exemplary embodiment;

FIG. 9 is a side view illustrating an electronic device system of a second exemplary embodiment;

FIG. 10 is a plan view illustrating an electronic device of the second exemplary embodiment in a partially enlarged manner;

FIG. 11 is a side view illustrating the electronic device of the second exemplary embodiment in a partially enlarged manner;

FIG. 12 is a side view illustrating an electronic device of a third exemplary embodiment in a partially enlarged manner;

FIG. 13 is a side view illustrating an electronic device of a fourth exemplary embodiment in a partially enlarged manner;

FIG. 14 is a side view illustrating an electronic device of the fifth exemplary embodiment in a partially enlarged manner; and

FIG. 15 is a side view illustrating the electronic device system of the first exemplary embodiment.

### DESCRIPTION OF EMBODIMENTS

A first exemplary embodiment will be described in detail with reference to the drawings.

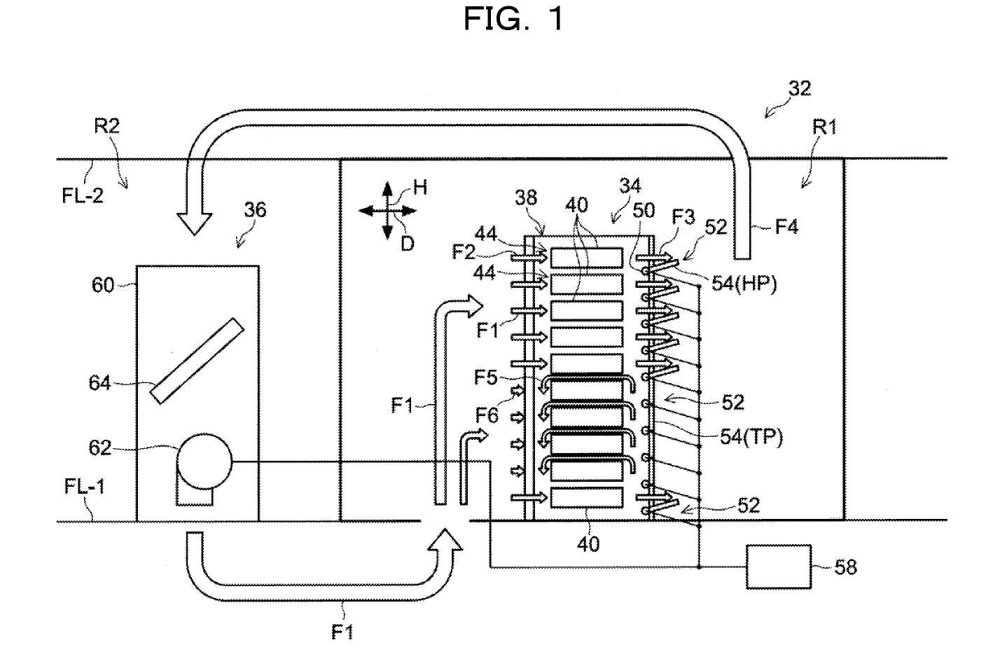

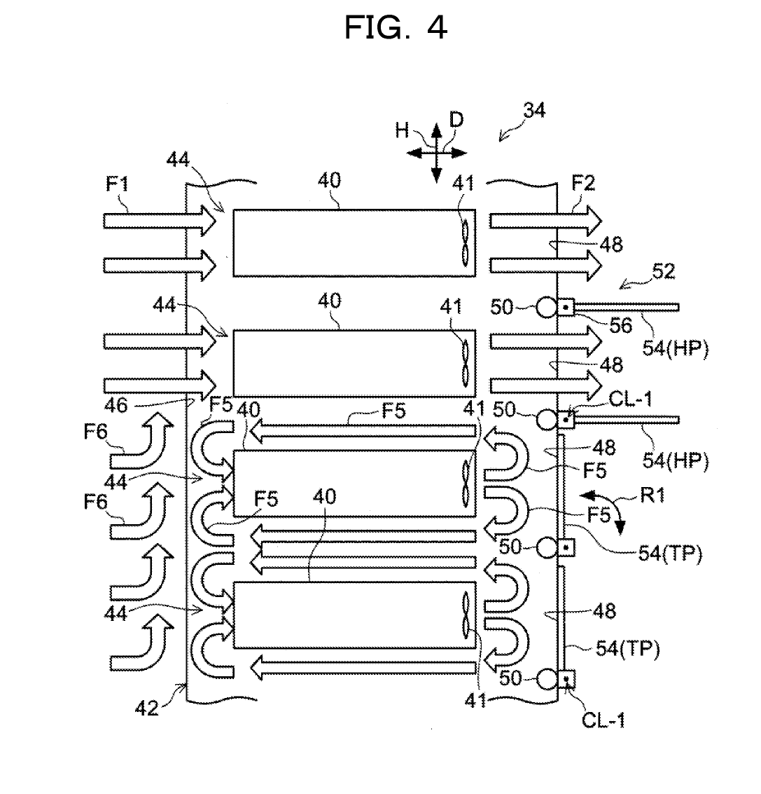

As illustrated in FIG. 1, an electronic device system 32 of the first exemplary embodiment includes an electronic device 34 and an air blower 36. Furthermore, the electronic device 34 includes a rack 38 and a plurality of pieces of electronic equipment 40 that are mounted in the rack 38. The electronic equipment 40 is a server, for example. As illustrated in FIG. 4, each piece of electronic equipment 40 may have a fan 41 that makes the air flow mounted therein.

The electronic device 34 is installed in a predetermined installation room R1 (a server room or the like), for example. Furthermore, the air blower 36 is installed in a predetermined installation room R2 that is different from the installation room R1.

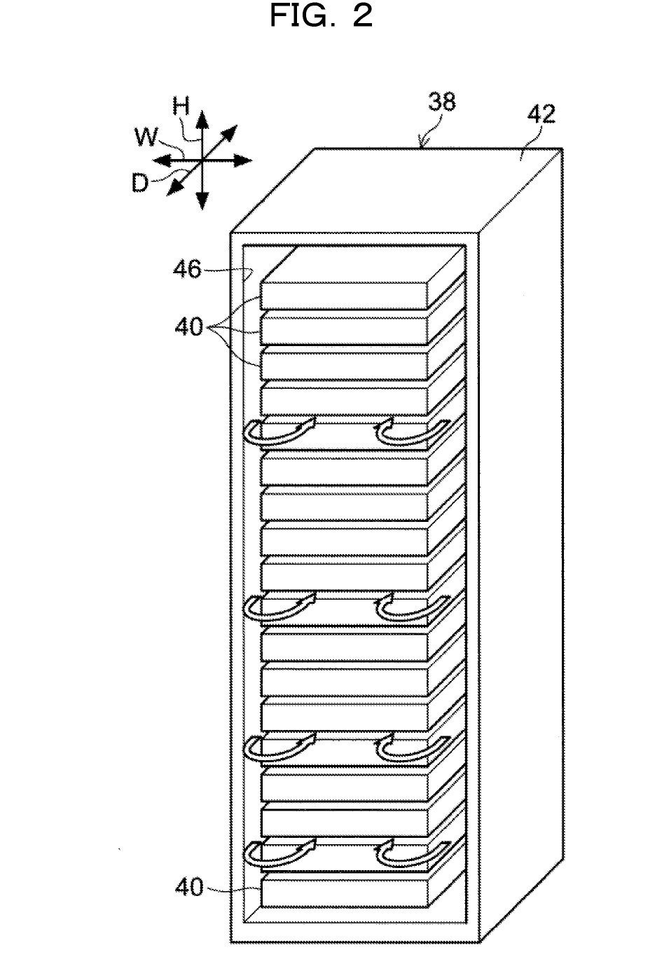

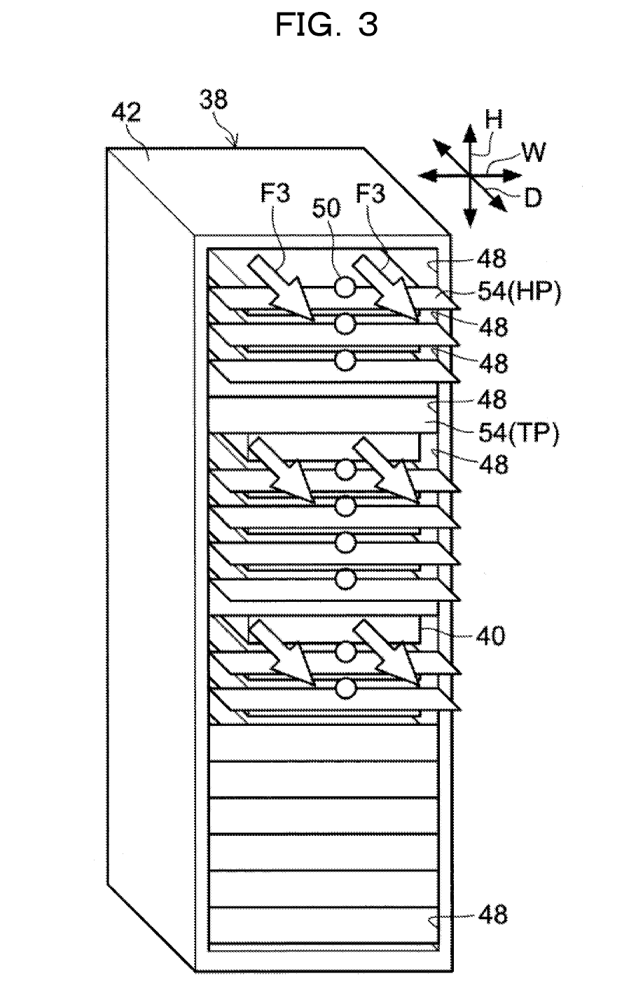

As illustrated in FIGS. 2 and 3, in the present exemplary embodiment, the rack 38 includes a rack body 42 that is formed in a rectangular parallelepiped box shape. A plurality of housing portions 44 that are aligned in the vertical direction are formed inside the rack body 42. A piece of electronic equipment 40 is housed in each of the housing portions 44. In other words, the rack body 42 has a structure that allows the plurality of pieces of electronic equipment 40 to be aligned and mounted in the vertical direction.

In the drawings, the vertical direction, the width direction, and the depth direction of the rack body 42 are indicated by an arrow H, an arrow W, and an arrow D, respectively.

As illustrated in FIG. 2, a face on a front side of the rack body 42 is open and the opening portion is an intake port 46. As illustrated in FIG. 3, a side (a backside) opposite to the intake port 46 is also open in its entirely.

As illustrated in FIG. 4, the opening portion on the backside has a structure in which a plurality of exhaust ports 48 are aligned in the vertical direction. In particular, in the present exemplary embodiment, the housing portions 44 and the exhaust ports 48 correspond to each other in a one-to-one manner. Furthermore, as illustrated by arrows F2 in FIG. 1, air sent from the air blower 36 enters the rack body 42 through the intake port 46. Then, the air passes through the inside of the rack body 42. As illustrated by arrows F3 in FIG. 1, the air that has passed through the inside of the rack body 42 is discharged to the outside of the rack body 42 through the exhaust ports 48 if the exhaust ports 48 are open.

Hereinafter, an “upstream side” and a “downstream side” refer to the upstream side and a downstream side, respectively, of the air that flows towards the exhaust ports 48 from the intake port 46 in the rack body 42.

A plurality of temperature sensors 50 are disposed in the exhaust ports 48. In the present exemplary embodiment, each of the temperature sensors 50 is provided in a corresponding one of the housing portions 44 in a one-to-one manner. The temperature sensors 50 are attached to cross-beams (not shown) inside the rack 38, for example. In particular, in the example illustrated in FIG. 3, the temperature sensors 50 are positioned in the middle of the exhaust ports 48 in the width direction (the direction of the arrow W).

A plurality of opening and closing devices 52 that open and close the exhaust ports 48 are attached to the rack 38. As it may be understood from FIG. 1, in the present exemplary embodiment, the opening and closing devices 52 are provided in a one-to-one manner with the housing portions 44 (the electronic equipment 40).

As illustrated in detail in FIG. 4, in the present exemplary embodiment, the opening and closing devices 52 each include an opening and closing door 54 and an actuator 56. Each opening and closing door 54 has a size that is capable of closing the corresponding exhaust port 48. In other words, the opening on the backside of the rack body 42 is divided into a plurality of exhaust ports 48 that are opened and closed by the opening and closing doors 54.

Each of the opening and closing doors 54 is rotatably supported by the corresponding actuator 56 between a position in which the corresponding exhaust port 48 is closed (a closed position TP) and a position in which the corresponding exhaust port 48 is open (an open position HP).

In the first exemplary embodiment, rotational centerlines CL-1 (the actuators 56) of the opening and closing doors 54 are located at lower ends of the opening and closing doors 54 when the opening and closing doors 54 are in the closed positions TP. As illustrated by arrows R-1, each of the opening and closing doors 54 rotates in an air discharge direction (in a direction of the arrow F3 or a direction opposite thereto) in the exhaust ports 48 so as to change the position of the opening and closing door 54 between the closed position TP and the open position HP. In particular, the first exemplary embodiment adopts a structure in which a single opening and closing door 54 opens and closes a single exhaust port 48.

The actuators 56 are each capable of positioning the corresponding opening and closing door 54 at a position (an intermediate position) between the closed position TP and the open position HP. By having the opening and closing doors 54 be in intermediate positions, opening ratios of the exhaust ports 48 may be changed. The opening ratio herein refers to a ratio of an area of the exhaust port 48 that is actually open to the opening area of the exhaust port 48 when the opening and closing door 54 is in the open position HP. The expression “changing the opening ratio of the exhaust port 48” includes the opening and closing door 54 made to be in the closed position TP and in the open position HP. For example, when the opening and closing door 54 is in the open position HP, the opening ratio is 100%, and when in the closed position TP, the opening ratio is 0 (zero) %.

As illustrated in FIG. 1, the electronic device system 32 includes a controller 58. Data of air temperature detected in each of the temperature sensors 50 is sent to the controller 58. The controller 58 controls the temperature sensors 50 so that the temperatures of the air are measured at a predetermined time interval (a sampling interval). Then, as described later, based on the acquired temperature data from the temperature sensors 50 and a threshold temperature that has been set, the controller 58 controls the actuators 56 and adjusts the opening and closing positions of the opening and closing doors 54.

As illustrated in FIG. 1, the air blower 36 includes a blower fan 62 and a heat exchanger 64 that are housed inside a housing 60. As illustrated by arrows F1, the air sent from the blower fan 62 passes through a lower side (an underfloor) of a floorboard FL-1 on which the air blower 36 and the rack body 42 are installed, and flows into the installation room R1. Then, the air flows into the rack body 42 through the intake port 46 of the rack body 42.

As illustrated by an arrow F4, the air that has passed through the rack body 42 and that has been discharged into the installation room R1 passes through an upper side of a ceiling FL-2 and, flowing through the installation room R2, enters the housing 60 of the air blower 36. The air is cooled inside the housing 60 by the heat exchanger 64 and is sent out to the outside of the housing 60 (to the underfloor) with the blower fan 62 again.

The blower fan 62 is controlled by the controller 58 so that an air blowing capacity (an amount of air sent per unit time) is set to a desired value.

A database that sets forth correlations between a closed rate R or a total opening ratio S that are described later and the air blowing capacity of the blower fan 62 is stored in the controller 58.

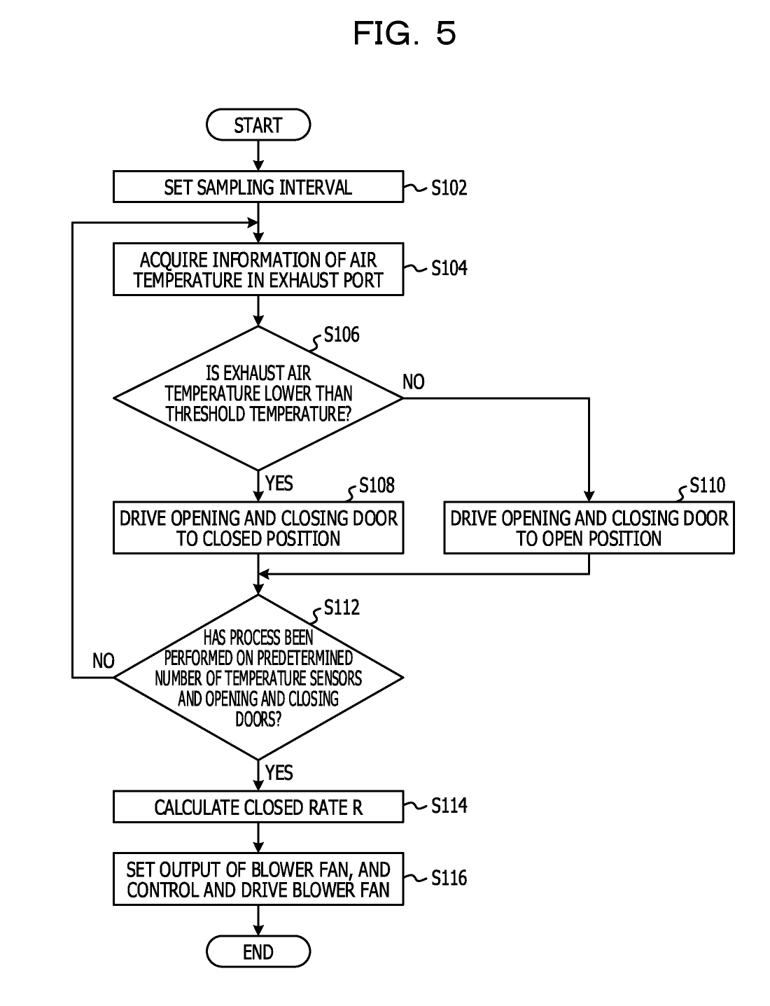

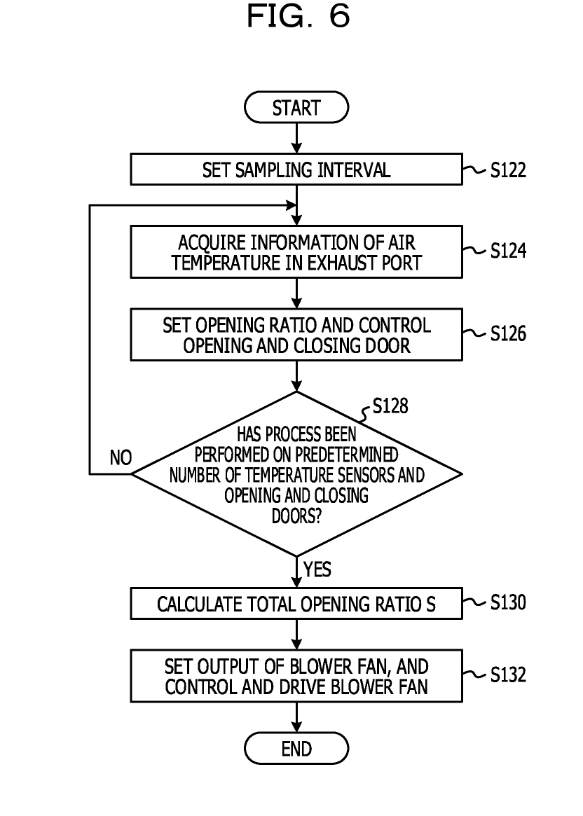

Referring next to the flowcharts in FIGS. 5 and 6, methods (electronic device cooling methods) for cooling the electronic device 34 (the electronic equipment 40) will be described.

Note that in the electronic device cooling methods, a control may be performed in which each of the opening and closing doors 54 is controlled to either one of the open position HP or the closed position TP (hereinafter referred to as “opening and closing control”) or a control may be performed so that the opening and closing doors 54 have optional opening ratios (hereinafter referred to as “opening ratio control”). The opening and closing control will be described first with reference to the flowchart in FIG. 5.

In the opening and closing control of the electronic device cooling method, the time interval (the sampling interval) at which the air temperatures in the exhaust ports 48 are measured by the temperature sensors 50 is set in step S102. The sampling interval may be a predetermined time interval stored in the controller 58 in advance or an operator may input a new sampling interval through a control panel or the like.

In step S104, the controller 58 acquires, at the above sampling interval, information of the air temperature (the exhaust air temperature) in an exhaust port 48 of the rack body 42 with a specific temperature sensor 50 (a temperature sensor that is positioned at the top, for example).

In step S106, the controller 58 compares the threshold temperature that has been set in advance and the air temperature (the exhaust air temperature) that has been measured by the temperature sensor 50 with each other. Then, when it is determined that the exhaust air temperature is lower than the threshold temperature, the process proceeds to step S108.

In step S108, the controller 58 controls and drives a relevant actuator 56 so that the opening and closing door 54 corresponding to the temperature sensor 50 that has measured the exhaust air temperature is in the closed position TP. With the above, in the housing portion 44 that correspond to the exhaust port 48 that has the exhaust air temperature that is lower than the threshold temperature, as illustrated by arrows F5, inside the rack body 42, the air is not discharged to the outside of the rack body 42 and goes around into the rack body 42. In other words, air with a low temperature is circulated inside the rack body 42 and is reused to cool the electronic equipment 40. As illustrated by arrows F6, in the intake port 46 on the upstream side of the opening and closing door 54 that is in the closed position TP, inflow of air into the rack body 42 is suppressed. Furthermore, since the exhaust port 48 is closed in the opening and closing door 54 that is in the closed position TP, no air (at a high temperature) of the installation room R1 will flow into the rack body 42 through the above exhaust port 48.

Conversely, in step S106, when it is determined that the exhaust air temperature is equivalent to or higher than the threshold temperature, the process proceeds to step S110.

In step S110, the controller 58 controls and drives a relevant actuator 56 so that the opening and closing door 54 corresponding to the temperature sensor 50 that has measured the exhaust air temperature is in the open position HP. With the above, as illustrated by the arrows F3, the air inside the rack body 42 is discharged to the outside through the exhaust port 48 in which the exhaust air temperature is equivalent to or higher than the threshold temperature. Furthermore, as illustrated by the arrows F2, the air that has been sent from the air blower 36 enters the rack body 42 through the intake port 46 on the upstream side of the opening and closing door 54 that is in the open position HP and flows inside the rack body 42.

In step S112, determination whether the above-described operation has been performed on a predetermined number (all, for example) of the temperature sensors 50 and the opening and closing devices 52 is made, and when the above-described operation has not been performed on the predetermined number of the above, the process returns to step S104. When it is determined that the above-described operation has been performed on the predetermined number of the temperature sensors 50 and the opening and closing devices 52, the process proceeds to step S114.

In step S114, the closed rate R of the entire exhaust ports 48 is obtained. Then, the process proceeds to step S116.

In step S116, the controller 58 sets the output of the blower fan 62 from the database of the relationship between the closed rate R obtained in step S114 and the output of the blower fan 62, and controls the drive of the blower fan 62.

As described above, in the opening and closing control of the electric device cooling method, in the exhaust ports 48 in which the exhaust air temperatures are low, the opening and closing doors 54 are set to the closed position TP. Since, inside the rack body 42, the air that has not reached the threshold temperature is circulated and is used (reused) to cool the electronic equipment 40, even if the amount of air that is actually sent to the rack body 42 from the air blower 36 is reduced, each piece of electronic equipment 40 may be cooled. Furthermore, even if the amount of air that is supplied to the electronic device 34 (the rack 38) from the air blower 36 is small, the electronic device 34 (each piece of electronic equipment 40) may be cooled efficiently.

The opening ratio control of the electronic device cooling method will be described next with reference to the flowchart in FIG. 6.

In step S122, a time interval (a sampling interval) at which the air temperature (the exhaust air temperature) of the exhaust port 48 is measured with the temperature sensor 50 is set.

Furthermore, in step S124, the controller 58 acquires, at the above sampling interval, information of the air temperature (the exhaust air temperature) in an exhaust port 48 of the rack body 42 with a specific temperature sensor 50. Step S122 and step S124 may be performed in a similar manner to step S102 and step S104 (see FIG. 5) in the opening and closing control.

Next, in step S126, based on the database setting forth the relationship between the information on the exhaust air temperature acquired in step S124 and the opening ratio, the controller 58 sets the opening ratio of the opening and closing door 54 corresponding to the temperature sensor 50 that has measured the exhaust air temperature. Then, the opening and closing position of the opening and closing door 54 is set to the desired opening and closing position so that the set opening ratio is reached (the actuator 56 is driven and controlled).

In the above, since the air does not easily flow out from the exhaust port 48 of the rack body 42 that has a small opening ratio, most of the air is not discharged to the outside of the rack body 42 and goes around inside the rack body 42. In other words, most of the air with a low temperature is circulated inside the rack body 42 and is reused to cool the electronic equipment 40. The amount of inflow of air into the rack body 42 is small in the intake port 46 on the upstream side of the opening and closing door 54 having the small opening ratio.

Conversely, most of the air inside the rack body 42 is discharged through the exhaust port 48 that has a large opening ratio. Furthermore, most of the air that has been sent from the air blower 36 enters the rack body 42 through the intake port 46 on the upstream side of the opening and closing door 54 that is in the open position HP.

In step S128, the controller 58 determines whether the above-described operation has been performed on a predetermined number (all, for example) of the temperature sensors 50 and the opening and closing devices 52, and when the above-described operation has not been performed on the predetermined number of the above, the process returns to step S124. When it is determined that the above-described operation has been performed on the predetermined number of the temperature sensors 50 and the opening and closing devices 52, the process proceeds to step S130.

In step S130, the opening ratio (the total opening ratio S) of the entire exhaust ports 48 is obtained. Then, the process proceeds to step S132. The calculation of the total opening ratio S is performed, for example, by adding the opening area of each of the exhaust ports 48 together (obtaining the sum) and dividing the sum by a sum of the opening areas of all the exhaust ports 48 that have an opening ratio of 100%.

In step S132, the controller 58 sets the output of the blower fan 62 from the database of the relationship between the total opening ratio S obtained in step S130 and the output of the blower fan 62, and controls the drive of the blower fan 62.

The above opening and closing control may be, when the electronic device system 32 is in operation, performed at a predetermined timing or, further, at an optional timing set by an instruction from the operator.

Furthermore, when the temperature of the air circulating inside the rack body 42 becomes high, the controller 58 changes the opening and closing doors 54 to the open position HP. With the above, the air inside the rack body 42, whose temperature has become equivalent to or above the threshold temperature, may be discharged to the outside of the rack body 42 through the exhaust ports 48. Then, fresh air may be introduced inside the rack body 42 through the intake port 46.

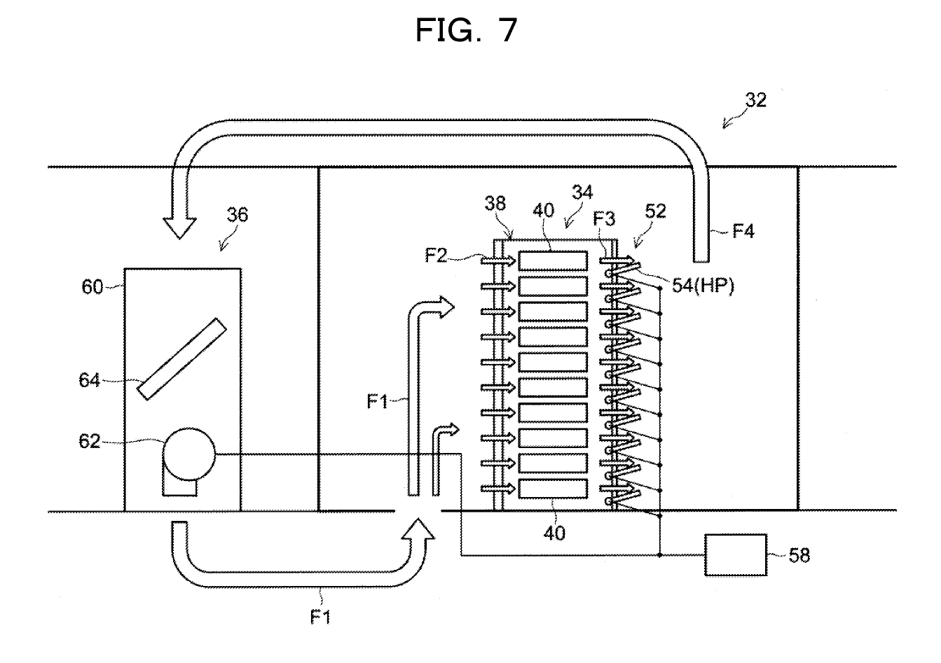

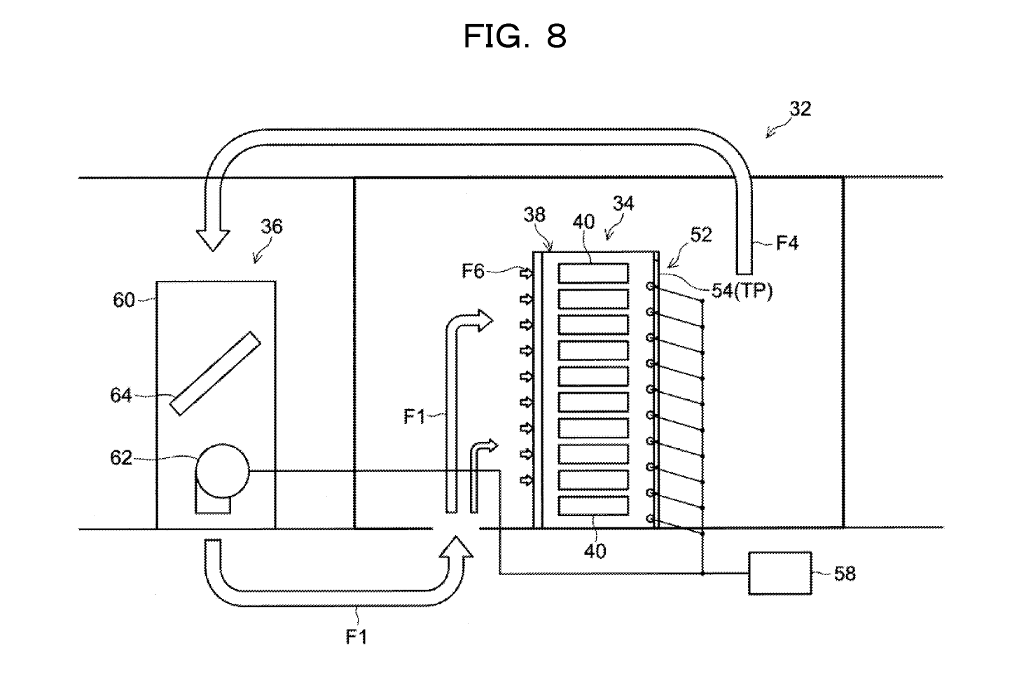

Note that when the exhaust air temperatures are high in all the exhaust ports 48, as illustrated in FIG. 7, a state in which all of the opening and closing doors 54 are in the open position HP may occur temporarily. Conversely, when the exhaust air temperatures are low in all the exhaust ports 48, as illustrated in FIG. 8, a state in which all of the opening and closing doors 54 are in the closed position TP may occur temporarily.

As described above, in the opening ratio control of the electronic device cooling method, the positions of the opening and closing doors 54 are adjusted so that the opening ratios are small in the exhaust ports 48 in which the exhaust air temperatures are low. Since, inside the rack body 42, the air that has a low temperature is circulated and is used (reused) to cool the electronic equipment 40, even if the amount of air that is actually sent to the rack body 42 from the air blower 36 is reduced, each piece of electronic equipment 40 may be cooled. The air is preferentially sent particularly to the electronic equipment 40 having a high temperature. Furthermore, for example, by reducing the amount of air sent from the blower fan 62, power consumed by the blower fan 62 may be reduced. Furthermore, even if the amount of air that is supplied to the electronic device 34 (the rack 38) from the air blower 36 is small, the electronic device 34 (each piece of electronic equipment 40) may be cooled efficiently.

Furthermore, since the air whose temperature has risen returns to the air blower 36, the efficiency of heat exchange in the heat exchanger 64 is high. For example, in the heat exchanger 64, even if the temperature of cold water (coolant) used to exchange heat is high, heat may be exchanged with the air and the energy taken to exchange heat may be reduced.

As it may be understood from the description described above, in the rack 38, the electronic device 34, and the electronic device system 32 of the present exemplary embodiment, air that has a low temperature at the exhaust ports 48 is circulated and reused inside the rack body 42. Accordingly, even if the total amount of air sent to the rack 38 is reduced, the electronic equipment 40 may be cooled and efficient cooling may be performed.

A description of a second exemplary embodiment will be given next. In the second exemplary embodiment, elements, components, and the like that are similar to those of the first exemplary embodiment are denoted with the same reference numerals and detailed descriptions thereof are omitted. Particularly, in the second exemplary embodiment, since the overall structures of the electronic device and the electronic device system are the same as those of the first exemplary embodiment, descriptions thereof are omitted.

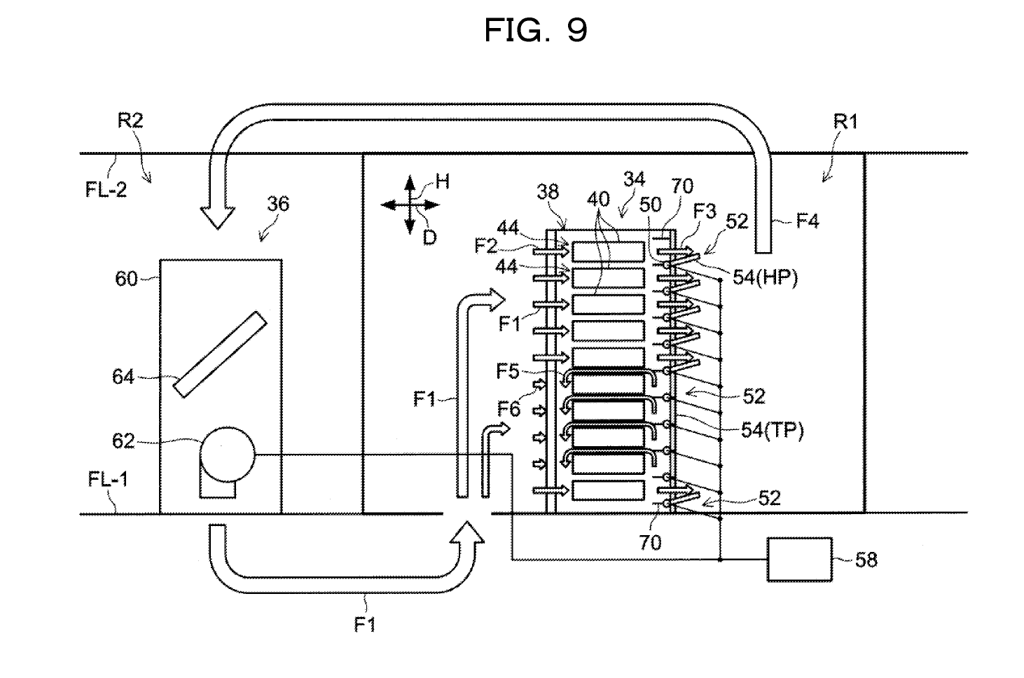

As illustrated in FIG. 9, a rack 68 of the second exemplary embodiment includes baffle plates 70. The baffle plates 70 are plate-shaped members that are provided in the housing portions 44 so as to be positioned at boundary portions of the plurality of exhaust ports 48. Furthermore, the baffle plates 70 are provided at the upper portion of the uppermost exhaust port 48 and at the lower portion of the lowermost exhaust port 48 as well.

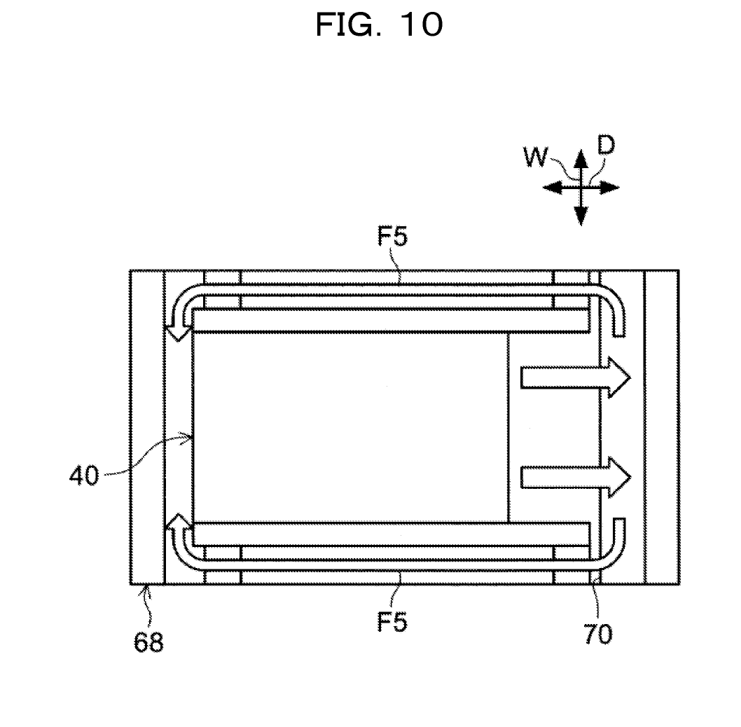

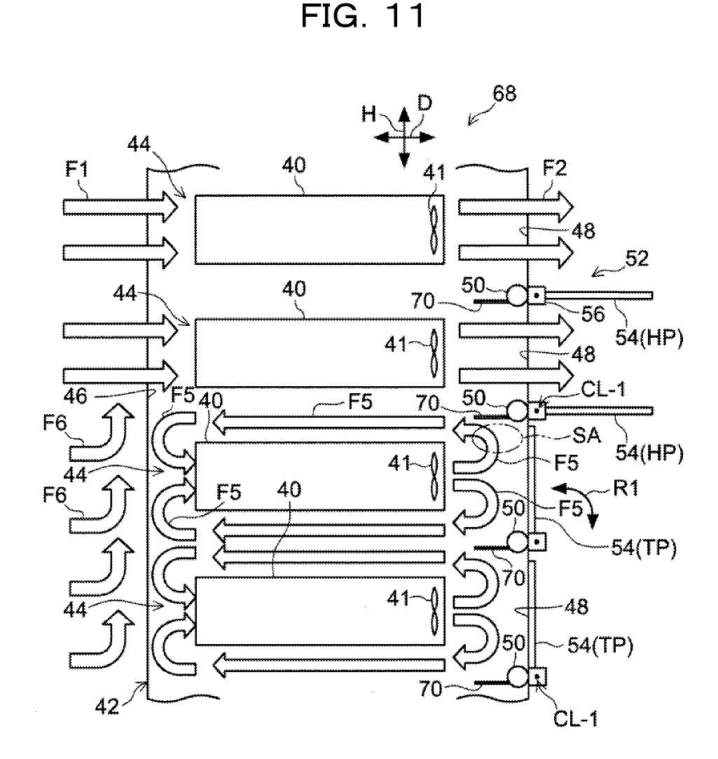

In an example illustrated in FIG. 10, the baffle plate 70 has a rectangular tabular shape in which the longitudinal direction of the baffle plate 70 coincides with the rack body 42 in the width direction (the arrow W direction), and the short direction coincides with the rack body 42 in the depth direction (the arrow D direction). Accordingly, as it may be understood from FIG. 11, in the short direction, the baffle plates 70 extend in a direction oriented from the intake port 46 towards the exhaust ports 48 in the rack body 42.

Similar to the first exemplary embodiment, the second exemplary embodiment adopts a structure in which a single opening and closing door 54 opens and closes a single exhaust port 48.

Since the second exemplary embodiment includes the baffle plates 70, the air inside the rack body 42 being unexpectedly discharged from a neighboring exhaust port 48 at a position close to the exhaust port 48 may be suppressed. For example, as it may be understood from FIG. 11, air SA that has not been discharged from the rack body 42 because the opening and closing door 54 is in the closed position TP is present at the boundary portion between the opening and closing door 54 in the closed position TP and the opening and closing door 54 in the open position HP. The air SA may be suppressed from being discharged from the exhaust port 48 on the upper side in which the opening and closing door 54 is in the open position HP in FIG. 11.

Note that the second exemplary embodiment is structured such that the centerline of rotation (the actuator 56) of each of the opening and closing doors 54 is positioned at the lower end of the corresponding opening and closing door 54 when the opening and closing door 54 is in the closed position TP. Conversely, the structure may be such that the centerline of rotation (the actuator 56) of each of the opening and closing doors 54 is positioned at the upper end of the corresponding opening and closing door 54 when the opening and closing door 54 is in the closed position TP.

A description of a third exemplary embodiment will be given next. In the third exemplary embodiment, elements, components, and the like that are similar to those of the first exemplary embodiment or the second exemplary embodiment are denoted with the same reference numerals and detailed descriptions thereof are omitted. In the third exemplary embodiment as well, since the overall structures of the electronic device and the electronic device system are the same as those of the first exemplary embodiment, descriptions thereof are omitted.

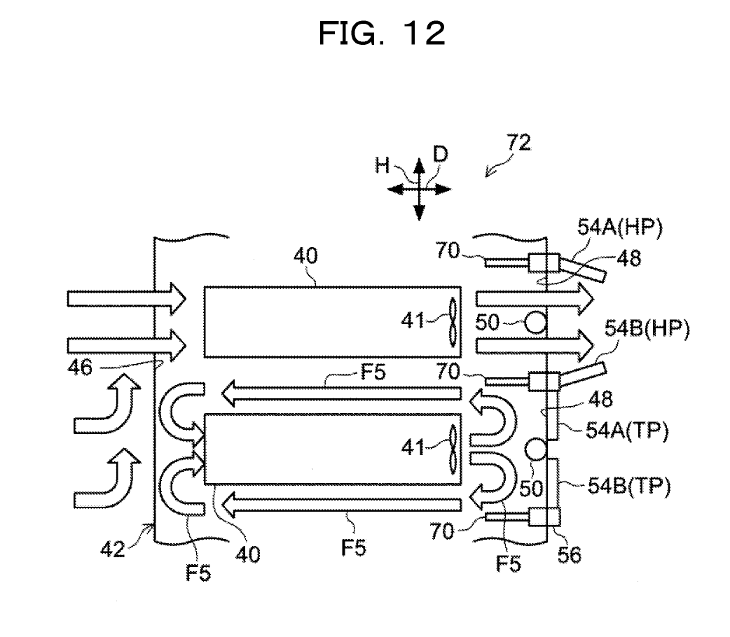

As illustrated in FIG. 12, a rack 72 of the third exemplary embodiment is provided with a pair of upper and lower opening and closing doors 54A and 54B in each of the exhaust ports 48. In the closed position TP of each of the opening and closing doors 54A and 54B, a rotation center of the opening and closing door 54A on the upper side is located at the upper end of the opening and closing door 54A and a rotation center of the opening and closing door 54B on the lower side is located at the lower end of the opening and closing door 54B. Furthermore, in the closed position TP, the opening and closing doors 54A and 54B reduce the opening ratio of the exhaust port 48 while being vertically continued or having a predetermined slight gap open between each other.

In the third exemplary embodiment, since the pairs of upper and lower opening and closing doors 54A and 54B are used, when the opening and closing doors 54A and 54B are in the open position HP, compared with the first and second exemplary embodiments, the length bulging out towards the back side (the right side in FIG. 12) is short. Contact between the opening and closing doors 54A and 54B and a device or a member that is disposed on the backside of the rack body 42 may be averted, for example.

On the other hand, in the first and second exemplary embodiments, since a single exhaust port 48 may be opened and closed (or the opening ratio may be changed) with a single opening and closing door 54, the structure may be more simple.

A description of a fourth exemplary embodiment will be given next. In the fourth exemplary embodiment, elements, components, and the like that are similar to those of the first to third exemplary embodiments are denoted with the same reference numerals and detailed descriptions thereof are omitted. In the fourth exemplary embodiment as well, since the overall structures of the electronic device and the electronic device system are the same as those of the first exemplary embodiment, descriptions thereof are omitted.

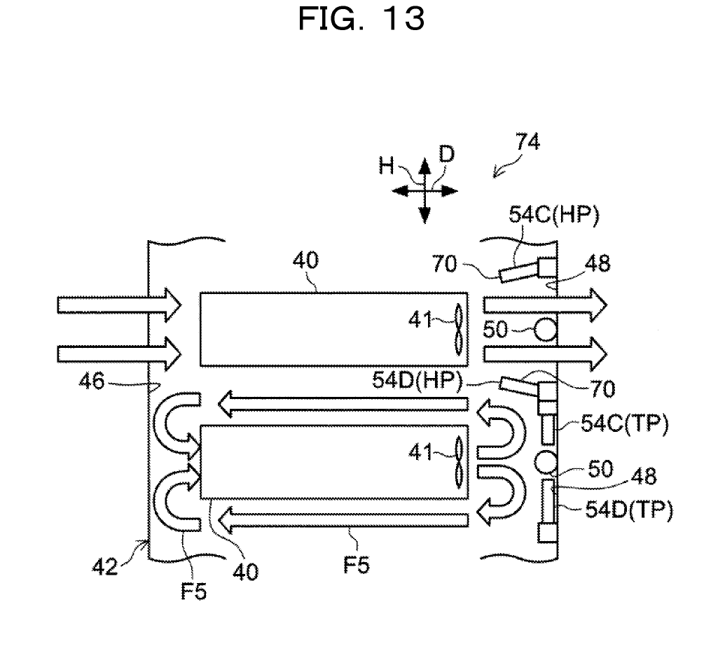

As illustrated in FIG. 13, while a rack 74 of the fourth exemplary embodiment is provided with a pair of upper and lower opening and closing doors 54C and 54D in each of the exhaust ports 48, the opening and closing doors 54C and 54D rotate towards the inside of the rack body 42 to take the open position HP. Furthermore, in the open position HP, the opening and closing doors 54C and 54D extend in a direction oriented towards the corresponding exhaust port 48 from the intake port 46 in the rack body 42. In other words, the opening and closing doors 54C and 54D in the open position HP also serves as the baffle plates 70 (see FIGS. 11 and 12).

Accordingly, in the fourth exemplary embodiment, since the opening and closing doors 54C and 54D that are in the open position HP also serves as the baffle plates 70, compared to a structure in which the opening and closing doors 54C and 54D and the baffle plates 70 are provided separately, the number of components is few.

A description of a fifth exemplary embodiment will be given next. In the fifth exemplary embodiment, elements, components, and the like that are similar to those of the first exemplary embodiment are denoted with the same reference numerals and detailed descriptions thereof are omitted. In the fifth exemplary embodiment as well, since the overall structures of the electronic device and the electronic device system are the same as those of the first exemplary embodiment, descriptions thereof are omitted.

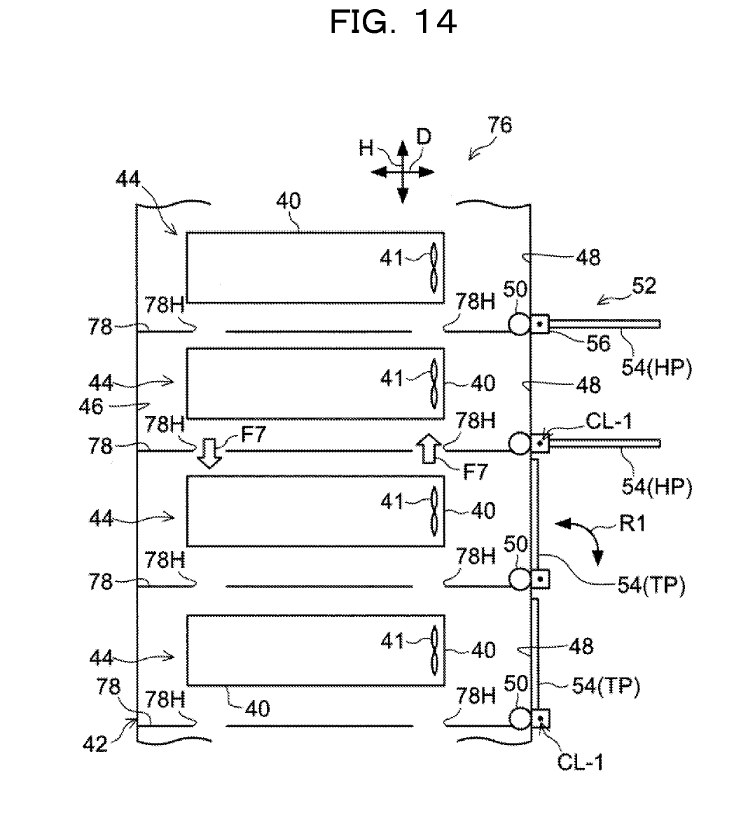

As illustrated in FIG. 14, a rack 76 of the fifth exemplary embodiment is provided with partition walls 78 inside the rack body 42. The partition walls 78 are positioned between the housing portions 44 and are each a plate-shaped member that partitions the housing portions 44.

Communication openings 78H are formed in each of the partition walls 78. In the example illustrated in FIG. 14, a total of two communication openings 78H, one on the upstream side and one on the downstream side, are formed. Owing to the communication openings 78H, the air may be moved between adjoining housing portions 44. Arrows F7 illustrated in FIG. 14 is an example of the directions in which the air moves; however, depending on the actual flow of air inside the housing portions 44, the air may move in directions opposite to those of the arrows F7.

In the fifth exemplary embodiment, the partition walls 78 act in a similar manner to the baffle plates 70 (see FIGS. 11 and 12). In other words, the air that has not been discharged from the closed exhaust ports 48 in which the opening and closing doors 54 are in the closed position TP may be suppressed from being discharged from the adjoining exhaust ports 48 in which the opening and closing doors 54 are in the open position HP.

The communication openings 78H are formed in the partition walls 78, and entering and exiting of air occurs in the housing portion 44 on the upstream side of the opening and closing door 54 in the closed position TP between the housing portion 44 on the upstream side of the opening and closing door 54 in the open position HP. The communication openings 78H are an example of communication portions. Furthermore, owing to the occurrence of entering and exiting of the air, stagnation of air inside the housing portion 44 on the upstream side of the opening and closing door 54 in the closed position TP may be suppressed and circulation of air may be created in a more efficient manner.

Note that in the first to fourth exemplary embodiments as well, moving of air is possible since no partition walls 78 are provided between the housing portions 44. In other words, in the first to fourth exemplary embodiments, the entirely of the inside of the rack body 42 is a communication portion that permits the air to move between the adjoining housing portions 44.

In each of the exemplary embodiments described above, the structure of the electronic equipment 40 is not limited in particular; however, the electronic equipment having a structure in which a fan 41 (see FIGS. 4, 11, and the like) that moves the air is mounted may be used. With the electronic equipment 40 in which the fan 41 is mounted, circulation of the air inside the housing portion 44 may be created more actively by driving the fan 41.

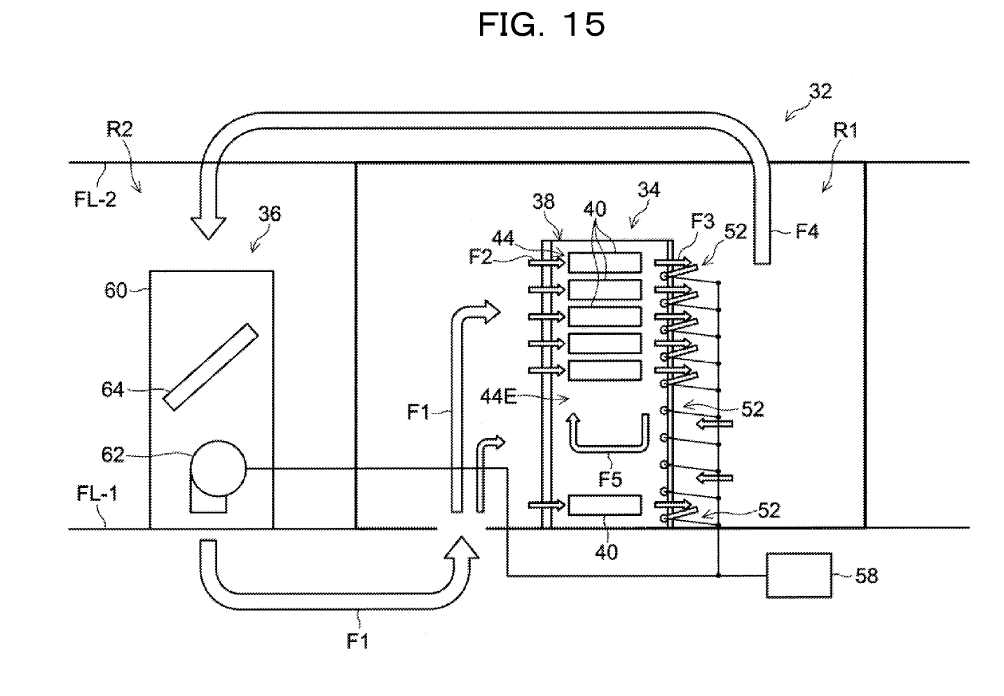

In each of the exemplary embodiments described above, examples in which the electronic equipment 40 is housed inside each and all of the plurality of housing portions 44 inside the rack body 42 has been illustrated; however, as illustrated in FIG. 15, for example, there may be a housing portion 44E in which no electronic equipment 40 is housed. In the housing portion 44E in which no electronic equipment 40 is housed, the air temperature does not rise; accordingly, the controller 58 maintains the opening and closing doors 54 on the downstream side in the closed position TP.

Furthermore, by maintaining the opening and closing doors 54 in the closed position TP, the air inside the installation room R1 is suppressed from reaching the electronic equipment 40 through the housing portion 44E (the area in which the electronic equipment 40 is not housed) inside the rack body 42.

Note that in the example illustrated in FIG. 15, movement of the air inside the rack body 42 also occurs in the housing portion 44E in which no electronic equipment 40 is housed. Accordingly, as illustrated by the arrow F5, in the housing portion 44E as well, the air goes around to the intake port side and is circulated.

In each of the exemplary embodiments described above, if there is a trend in the change in the exhaust air temperatures measured by the temperature sensors 50, the controller 58 may change the air blowing capacity of the blower fan 62 according to the trend in the temperature change. With the above, since the amount of inflowing air may be adjusted by estimating the air temperature change in the rack body 42, excessive increase in the air temperature may be suppressed, for example.

Particularly, the change in the air blowing capacity of the blower fan 62 may be performed prior to the rotation of the opening and closing doors 54. For example, when the exhaust air temperature is lower than the threshold temperature and has a rising trend, and when it is estimated that the exhaust air temperature will reach the threshold temperature in a short time, the air blowing capacity of the blower fan 62 may be increased before the exhaust air temperature reaches the threshold temperature. With the above, a large increase in the exhaust air temperature greatly exceeding the threshold temperature may be suppressed.

Furthermore, time (reaching time) taken for the air to reach the rack body 42 from the air blower 36 may be known beforehand according to the flow velocity of the air, the distance from the air blower 36 to the rack body 42, and the like. Accordingly, by changing the air blowing capacity of the blower fan 62 prior to the rotation of the opening and closing doors 54 while considering both the trend in the change in the exhaust air temperature described above and the reaching time, the electronic device 34 may be cooled in a further reliable manner.

In each of the exemplary embodiments described above, in the rack body 42, the temperature sensor 50 and the opening and closing door 54 are provided in each of the plurality of housing portions 44 in a one-to-one manner. For example, the structure may be such that a single temperature sensor 50 and a single opening and closing door 54 are provided in the plurality of housing portions 44. Compared with the above, each of the exemplary embodiments described above are capable of performing adjustment in each of the plurality of pieces of electronic equipment 40 on whether the air for cooling is to be circulated inside the rack body 42.

The opening and closing doors in each of the exemplary embodiments described above may each have a structure that slides in the width direction or in the vertical direction of the rack body 42, for example. However, in a structure in which the opening and closing doors are slid in the vertical direction, since the slide door in the open position covers the neighboring exhaust port, it is difficult to obtain an opening area of the exhaust port. In a structure in which the opening and closing doors are slid in the width direction, in order to obtain a large opening area of the exhaust port, the opening and closing door that is in the open position bulges out in the width direction of the rack body.

Conversely, in the exemplary embodiments described above, the rotational centerlines CL-1 (see FIG. 4) of the opening and closing doors 54, 54A, 54B, 54C, and 54D extend along the width direction of the rack body 42. Furthermore, the opening and closing doors 54, 54A, 54B, 54C, and 54D rotate in the air discharge direction with respect to the rack body 42. As described above, in the structure in which the exhaust ports 48 are opened and closed by rotation in the air discharge direction, when the opening and closing doors are in the open position, large opening areas of the exhaust ports 48 may be obtained and the amount of each of the opening and closing doors bulging out from the rack body 42 may be reduced.

In each of the exemplary embodiments described above, the opening and closing device includes the controller that controls the plurality of opening and closing doors based on the air temperatures measured by the plurality of temperature sensors 50. Conversely, a structure in which a controller is provided for each temperature sensor and opening and closing door may be adopted. Compared with the structure in which a controller is provided for each temperature sensor and opening and closing door, each of the exemplary embodiments described above is capable of reducing the number of controllers. As it may be understood from FIG. 1, actually, one controller 58 is sufficient. Moreover, since the controller controls the plurality of opening and closing doors, the closed rate R and the total opening ratio S of the rack body 42 as a whole may be easily calculated.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A cooling device comprising:
a rack body that houses a plurality of pieces of electronic equipment;
a plurality of temperature sensors that detect temperatures of air discharged from a plurality of exhaust ports of the rack body; and
an opening and closing device that increases an opening ratio of an exhaust port in which a temperature of the air detected with a temperature sensor is equivalent to or higher than a threshold temperature, and that decreases an opening ratio of an exhaust port in which a temperature of the air is lower than the threshold temperature.

2. The cooling device according to claim 1,
wherein the opening and closing device further comprises
a plurality of opening and closing doors that each open and close a corresponding one of the exhaust ports, and
a controller that, based on the temperatures of the air measured with the plurality of temperature sensors, controls each of the plurality of opening and closing doors.

3. The cooling device according to claim 2,
wherein the controller is provided outside the rack body.

4. The cooling device according to claim 2,
wherein the opening and closing doors change opening ratios by rotating in a discharge direction of the air.

5. The cooling device according to claim 1, further comprising
a baffle plate that is positioned at a boundary between the plurality of exhaust ports and that extends in a direction oriented from an intake port of the air towards the exhaust ports.

6. The cooling device according to claim 5,
wherein opening and closing doors change the opening ratios by rotating in a discharge direction of the air and becomes baffle plates when in an open position in which the exhaust ports are open.

7. The cooling device according to claim 2,
wherein rotation centers of the opening and closing doors are positioned at upper ends or lower ends of the plurality of exhaust ports such that the exhaust ports are each opened and closed with a corresponding one of the single opening and closing doors.

8. The cooling device according to claim 2,
wherein rotation centers of the opening and closing doors are positioned at upper ends and lower ends of the plurality of exhaust ports such that the exhaust ports are each opened and closed with a pair of upper and lower opening and closing doors.

9. The cooling device according to claim 2,
wherein the temperature sensors and the opening and closing doors are each provided in a housing portion of the corresponding electronic equipment of the rack body in a one-to-one manner.

10. The cooling device according to claim 1,
wherein the rack body further comprises
a communication portion that communicates housing portions that house the plurality of pieces of electronic equipment to each other and that permits the air to move.

11. A method of cooling an electronic device in an electronic device system including a plurality of pieces of electronic equipment, a rack body that houses the plurality of pieces of electronic equipment, a plurality of temperature sensors that detect temperatures of air discharged from a plurality of exhaust ports provided in the rack body, an opening and closing device that changes opening ratios of the exhaust ports, and an air blower that sends air to an air intake port of the rack body and to where the air that has been discharged from the exhaust port returns, the method comprising:
increasing an opening ratio of an exhaust port in which a temperature of the air detected with a temperature sensor is equivalent to or higher than a threshold temperature, and decreasing an opening ratio of an exhaust port in which a temperature of the air is lower than the threshold temperature with the opening and closing device.

12. The method of cooling an electronic device according to claim 11, further comprising
changing an air blowing capacity of the air blower in accordance with the opening ratios of the exhaust ports.

13. The method of cooling an electronic device according to claim 11, further comprising
changing an air blowing capacity of the air blower in accordance with the change in the temperatures detected by the temperature sensors.

14. The method of cooling an electronic device according to claim 13, further comprising
changing the air blowing capacity, the air blowing capacity being changed in accordance with the change in the temperatures detected by the temperature sensors, prior to changing the opening ratios.

15. The method of cooling an electronic device according to claim 14, further comprising
changing the air blowing capacity in accordance with a time in which the air takes to reach the rack body from the air blower.
